(19) United States
(12) Patent Application Publication
(10) Pub. No.: US 2025/0275476 A1
(43) Pub. Date: Aug. 28, 2025

(54) CUTTING TOOL WITH THERMOELECTRIC POWER GENERATION MODULE

(71) Applicant: INTERNATIONAL BUSINESS MACHINES CORPORATION, ARMONK, NY (US)

(72) Inventors: Sarbajit K. Rakshit, Kolkata (IN); Sudheesh S. Kairali, Kozhikode (IN); Binoy Thomas, Kozhikode (IN)

(21) Appl. No.: 18/585,151

(22) Filed: Feb. 23, 2024

(51) Int. Cl. H10N 10/13; B23B 27/10

(52) U.S. Cl. CPC H10N 10/13; B23B 27/10

(57) ABSTRACT

A cutting tool with an integrated thermoelectric power generation (TEPG) module includes a body and a cutting blade. The cutting tool with the TEPG module further includes the TEPG module disposed in a cavity of the body of the cutting tool. A method for utilizing the cutting tool with the TEPG module includes identifying a cutting operation and monitoring temperature for one or more sensors for the cutting tool with the integrated TEPG module. The method further includes determining a temperature threshold has been reached for at least one sensor from the one or more sensors and activating coolant fluid flow towards the cutting tool with the integrated TEPG module. The method further includes generating, by the TEPG module, power based on a temperature difference from heat generated by the cutting operation and a coolant fluid temperature.

### BACKGROUND

This disclosure relates generally to cutting tools, and in particular to a lathe cutting tool with an integrated thermoelectric power generation module.

A cutting tool, such as those utilized on a lathe, typically generate a considerable amount of heat as a blade of the cutting tool removes material from a metal body. The heat generated during the cutting process varies widely based on factors such as cutting speed, feed rate, material properties, tool geometry, and a cutting process type. During the cutting process, a temperature at the cutting zone, commonly referred to as the tool-chip interface, can reach temperatures greater than 1200° C. depending on the material of the metal body and the cutting conditions. A temperature at the tip of the cutting tool with a cutting blade can reach temperatures greater than of 1300° C., where the heat generated at the cutting blade can result in a softening of the metal body, tool wear, affected surface finish, and thermal damage. Cooling in the form of lubrication is typically utilized to manage the heat, where monitoring and controlling the temperature during the cutting process is essential for optimizing efficiency and ensuring the quality of machined parts.

### SUMMARY

One aspect of an embodiment of the present invention discloses an apparatus for a cutting tool with an integrated thermoelectric power generation (TEPG) module, the apparatus comprising a body and a cutting blade and the TEPG module disposed in a cavity of the body of the cutting tool.

Another aspect of an embodiment of the present invention discloses a method for utilizing a cutting tool with an integrated thermoelectric power generation (TEPG) module, the method comprising identifying a cutting operation for the cutting tool with the TEPG module. The method further comprises monitoring temperature for one or more sensors for the cutting tool with the integrated TEPG module. The method further comprises determining a temperature threshold has been reached for at least one sensor from the one or more sensors, activating coolant fluid flow towards the cutting tool with the integrated TEPG module. The method further comprises generating, by the TEPG module, power based on a temperature difference from heat generated by the cutting operation at a first end of the cutting tool with the integrated TEPG module and the coolant fluid at a second end of the cutting tool with the integrated TEPG module.

### BRIEF DESCRIPTION OF THE SEVERAL VIEWS OF THE DRAWINGS

FIG. 1 is a functional block diagram illustrating a computing environment, in accordance with an embodiment of the present invention.

FIG. 2 depicts a flowchart of a thermoelectric power generation module (TEPG) cutting tool program for identifying cutting operations and managing coolant flow to a cutting tool with an integrated TEPG, in accordance with an embodiment of the present invention.

FIG. 3 depicts a process flow for how a cutting tool with an integrated TEPG that generates power for multiple sensors positioned on a tool holder, in accordance with an embodiment of the present invention.

FIG. 4 depicts a side view of a cutting tool with a cavity for an integrated TEPG, in accordance with an embodiment of the present invention.

FIG. 5 depicts a three-dimensional view of a cutting tool with a cavity for an integrated TEPG, in accordance with an embodiment of the present invention.

FIG. 6 depicts a side view of a cutting tool with an integrated TEPG generating power while cutting a metal body with a coolant fluid being applied, in accordance with an embodiment of the present invention.

FIG. 7 depicts a side view of a cutting tool with a cavity for an integrated TEPG

and a channel for directing coolant fluid, in accordance with an embodiment of the present invention.

FIG. 8 depicts a three-dimensional view of a cutting tool with a cavity for an integrated TEPG and a channel for directing coolant fluid, in accordance with an embodiment of the present invention.

FIG. 9 depicts a three-dimensional view of a cutting tool with a cavity for an integrated TEPG and an enclosed channel for directing coolant fluid, in accordance with an embodiment of the present invention.

### DETAILED DESCRIPTION

Embodiments of the present invention provide a cutting tool with an integrated thermoelectric power generation (TEPG) module, where the TEPG module is disposed in a cavity of the cutting tool. The cavity of the cutting tool is such that a structural integrity of the cutting tool is not compromised due to the mechanical stresses and temperatures associated with a cutting process. A first end of the TEPG module is positioned within the cavity of the cutting tool and near a cutting blade where heat is generated during the cutting process. A second end of the TEPG module is positioned within the cavity of cutting tool opposite the cutting blade, where a coolant fluid is applied to an area where the second end of the TEPG module is positioned. A temperature difference between the first end and the second end of the TEPG module allow for electrical energy to be generated through the Seebeck effect. The TEPG module is disposed within the cavity of the cutting tool and secured to the body of the cutting tool utilizing one or more securing mechanisms that include but are not limited to clamps, fasteners, and adhesives. During the cutting process, coolant fluid is applied to the metal body being machined along with the cutting tool, where the coolant fluid can flow around the TEPG module disposed in the cavity of the cutting tool. The cutting tool and/or a tool holder can include one or more channels and/or passages for directing coolant fluid to the second of the TEPG module. The TEPG module can be incorporated in existing cutting tools that include a cavity or the cutting tool can be molded to include the cavity for placement and securement of the TEPG module.

The TEPG module can generate electrical energy (i.e., power) and transfer the electric energy to the tool holder and/or the cutting machine performing the cutting process. The electrical energy can be stored in a battery and/or capacitor, or can power one or more sensors (e.g., temperature) and/or devices (e.g., valves, pumps) required for the cutting process and the coolant fluid system. The TEPG module can include a circuit for managing the generated electric energy, the voltage level, and the transfer of the electric energy to the tool holder and/or the cutting machine. A circuit portion of the TEPG module is electrically insulated and heat insulated within the cavity of the cutting tool to protect the circuit from the heat generated during the cutting process and the coolant fluid that flows around the cutting tool. Wiring and/or one or more contact lead and contact pads between the TEPG module and the tool holder provide the electrical connection to transfer the generated electrical energy. Circuitry on the tool holder and/or the cutting machine can receive the electrical energy and disperse the power to the power storage device, the sensors, and/or the devices utilized during the cutting process.

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments. It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

Embodiments of the present invention provide a variable solar panel assembly with a number of advantages. A conventional solar panel utilizes visible light to generate electrical energy and typically produces manufacturer rated power at 25° C. If the conventional solar panel gets too hot (e.g., 70° C.), the conventional solar panel overheats, and efficiency is adversely impacted. Instances where a mirror panel is utilized to direct visible light towards the conventional solar panel, overheating can occur quicker due to the focused nature of the visible light, infrared (IR) spectrum waves, and ultraviolet (UV) spectrum waves on the conventional solar panel. A first advantage of the variable solar panel assembly includes a transparent solar panel absorbing the IR spectrum waves and UV spectrum waves prior to the IR spectrum waves and UV spectrum waves impacting and reflecting off the mirror panel towards the conventional solar panel. With the transparent solar panel absorbing the IR spectrum waves and UV spectrum waves, the amount of heat experienced by the conventional solar panel is reduced. A second advantage of the variable solar panel assembly includes the transparent solar panel generating electrical energy that would have otherwise been lost due to the conventional solar panel not being to covert the IR spectrum waves and UV spectrum waves. A third advantage of the variable solar panel assembly includes the conventional solar panel remaining under an ideal operational temperature range to efficiently covert visible light to electrical energy. A fourth advantage of the variable solar panel assembly includes the adjustability of a triangular prism configuration of the variable solar panel assembly that allows for the mirror panel to be positioned in a manner to optimize a light path towards the conventional solar panel.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

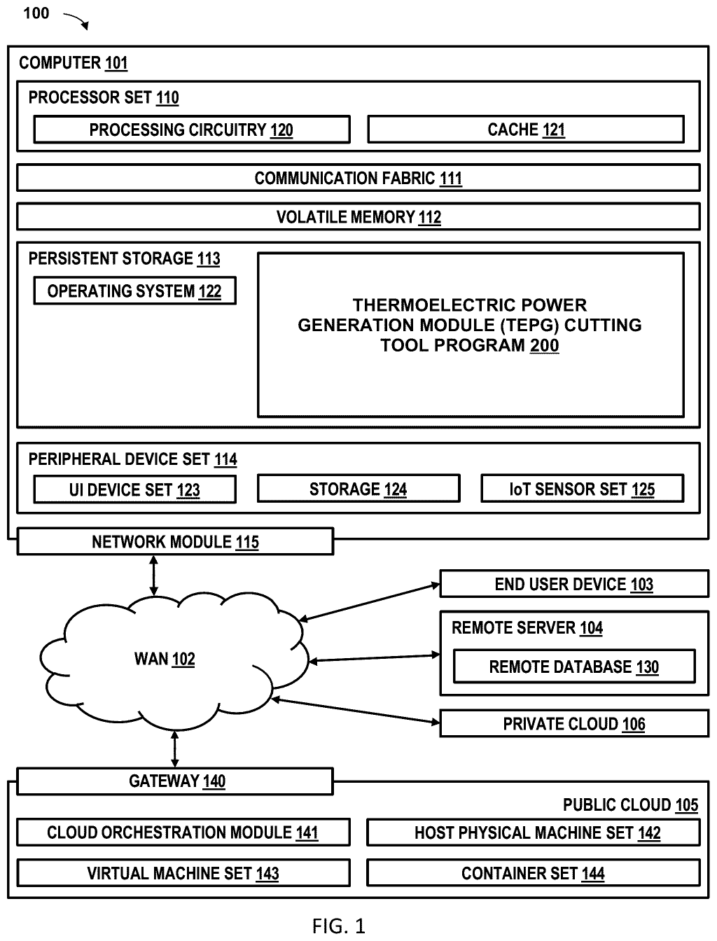

FIG. 1 is a functional block diagram illustrating a computing environment, generally designated 100, in accordance with one embodiment of the present invention. FIG. 1 provides only an illustration of one implementation and does not imply any limitations with regard to the environments in which different embodiments may be implemented. Many modifications to the depicted environment may be made by those skilled in the art without departing from the scope of the invention as recited by the claims.

Computing environment 100 contains an example of an environment for the execution of at least some of the computer code involved in performing the inventive methods, such as, thermoelectric power generation module (TEPG) cutting tool program 200. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

Computer 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

Processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

Communication fabric 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End User Device (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economics of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

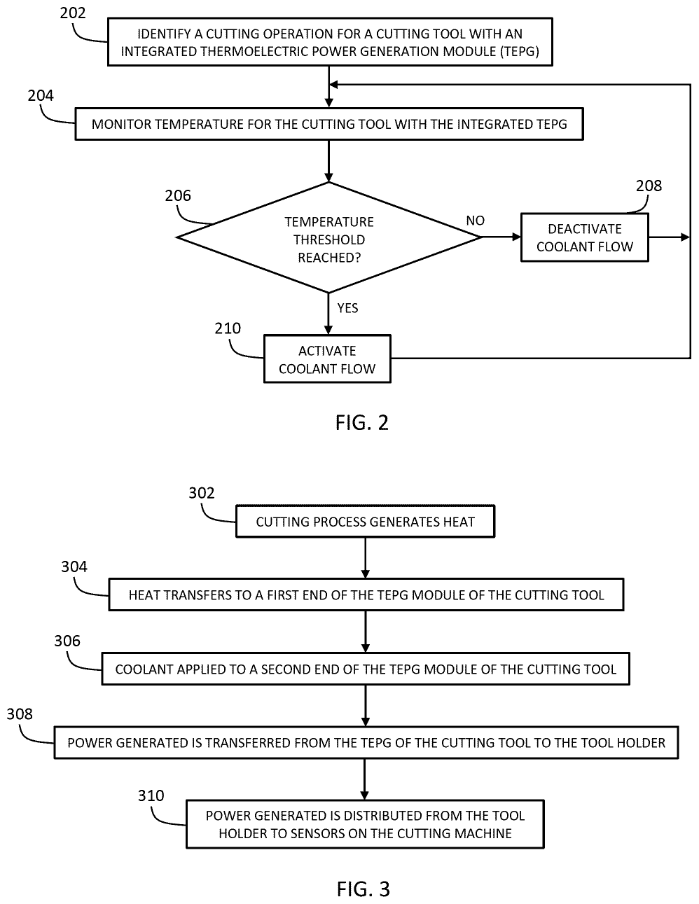

FIG. 2 depicts a flowchart of a thermoelectric power generation module (TEPG) cutting tool program for identifying cutting operations and managing coolant flow to a cutting tool with an integrated TEPG, in accordance with an embodiment of the present invention.

TEPG cutting tool program 200 identifies a cutting operation for a cutting tool with an integrated TEPG (202). In this embodiment, a metal body is placed on a cutting machine (e.g., lathe), where a cutting tool is to cut into the metal body to machine a final product. Subsequent to the cutting machine spinning the metal body and the cutting tool with the integrated TEPG contacting a surface of the rotating metal body, heat is generated due to the friction that exists between a cutting blade of the cutting tool with the integrated TEPG and the surface of the metal body. TEPG cutting tool program 200 receive readings from one or more temperature sensors positioned on the cutting tool with the integrated TEPG, the tool holder, and/or a surrounding region where a cutting blade contacts a cutting surface. TEPG cutting tool program 200 can identify a cutting operation based on an increased temperature reading from the one or more sensors. TEPG cutting tool program 200 can utilize a temperature threshold (e.g., 100° C.) and/or a temperature change rate (e.g., 10° C. per second) to identify that the cutting operation is in progress for the cutting tool with the integrated TEPG.

TEPG cutting tool program 200 monitors the temperature for the cutting tool with the integrated TEPG (204). TEPG cutting tool program 200 monitors the temperature for the cutting tool with the integrated TEPG by receiving readings for each of the one or more temperature sensors. Since each cutting process is unique due to variations in material properties of the metal body, tool wear, cutting speed, and feed rate, TEPG cutting tool program 200 continuously monitors the readings for each of the one or more temperature sensors to ensure optimal conditions for the cutting process. TEPG cutting tool program 200 can also analyze temperature trends and fluctuations to determine a level of heat generated, where the analyzing of the temperature trends can for example provide an indication of variations in materials (e.g., counterfeit material) and an indication of wear to a cutting blade of the cutting tool with the integrated TEPG.

TEPG cutting tool program 200 determines whether a temperature threshold has been reached (decision 206). TEPG cutting tool program 200 can utilize predefined temperature (i.e., heat) thresholds for different types of cutting operations which provide TEPG cutting tool program 200 indications on when to activate or deactivate coolant flow to the cutting tool with the integrated TEPG. In the event TEPG cutting tool program 200 determines a temperature has not been reached (“no” branch, decision 206), TEPG cutting tool program 200 deactivates coolant flow (208). TEPG cutting tool program 200 deactivating the coolant flow represents an instance where coolant flow was not flowing towards the cutting tool with the integrated TEPG and remains deactivated, or where coolant flow was flowing towards the cutting tool with the integrated TEPG and TEPG cutting tool program 200 determines to deactivate the coolant flow based on the temperature falling below the threshold. In the event TEPG cutting tool program 200 determines a temperature has been reached (“yes” branch, decision 206), TEPG cutting tool program 200 activates coolant flow (210).

TEPG cutting tool program 200 activates the coolant flow by instructing a control system on the cutting machine to release coolant fluid, where the control circulation system includes one or more valve and/or pumps to direct the coolant fluid towards the cutting tool with the integrated TEPG. TEPG cutting tool program 200 reverts to monitoring the temperature for the cutting tool with the integrated TEPG with the coolant fluid applies and can adjust a temperature of the coolant fluid utilizing a heater and/or chiller within the coolant circulation system. In some embodiments, TEPG cutting tool program 200 monitors a temperature of the coolant fluid within the coolant circulation system utilizes one or more temperature sensors and adjusts the temperature of the coolant fluid of the coolant fluid utilizing a heater and/or chiller within the coolant circulation system prior to the coolant being directed towards the cutting tool with the integrated TEPG. The cutting machine can utilize a closed loop for the coolant circulation system, where cool fluid directed towards the cutting tool with the integrated TEPG is captured and directed back into a chiller within the coolant circulation system.

FIG. 3 depicts a process flow for how a cutting tool with an integrated TEPG that generates power for multiple sensors positioned on a tool holder, in accordance with an embodiment of the present invention. The process flow for how a cutting tool with an integrated TEPG that generates power includes the cutting tool with the integrated TEPG contacting a metal body, where the cutting tool with the integrated TEPG begins removing material from the metal body during a cutting process. The cutting process generates heat (302), the heat transfers to a first end of the TEPG module of the cutting tool (304), and a coolant fluid is applied to a second end of the TEPG module of the cutting tool (306). Based on the temperature differences between the first end of the TEPG module and the second end of the TEPG module, power is generated by the TEPG module. The power generated is transferred from the TEPG module of the cutting tool to the tool holder (308) and subsequently, the power generated is distributed from the tool holder to the sensors on the cutting machine. In some embodiments, TEPG cutting tool program 200 estimates an amount of power generated by the TEPG module of the cutting tool and determines a distribution of the power generated to one or more sensors (e.g., temperature sensor) and/or devices (e.g., power storage device, pumps, valves) on the cutting machine.

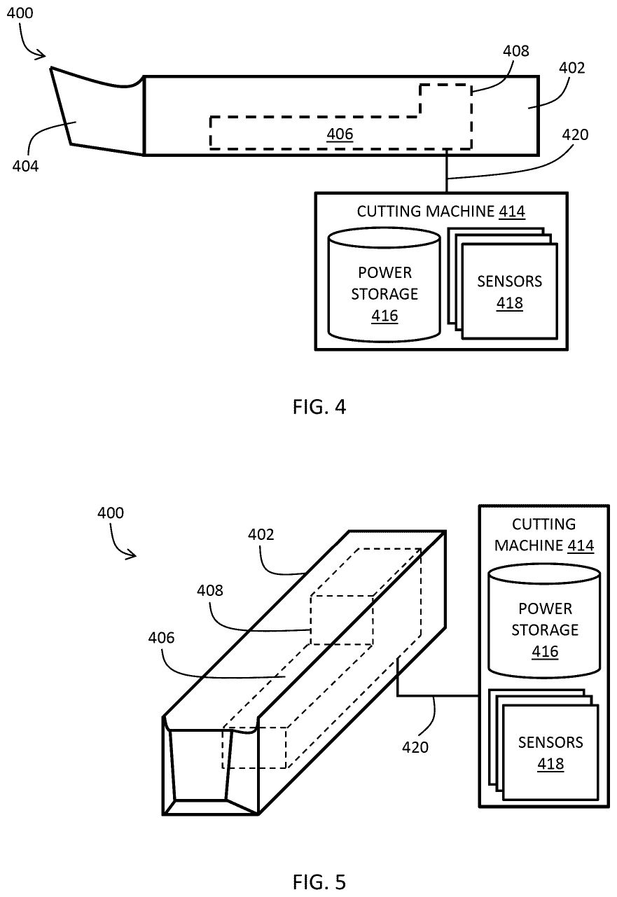

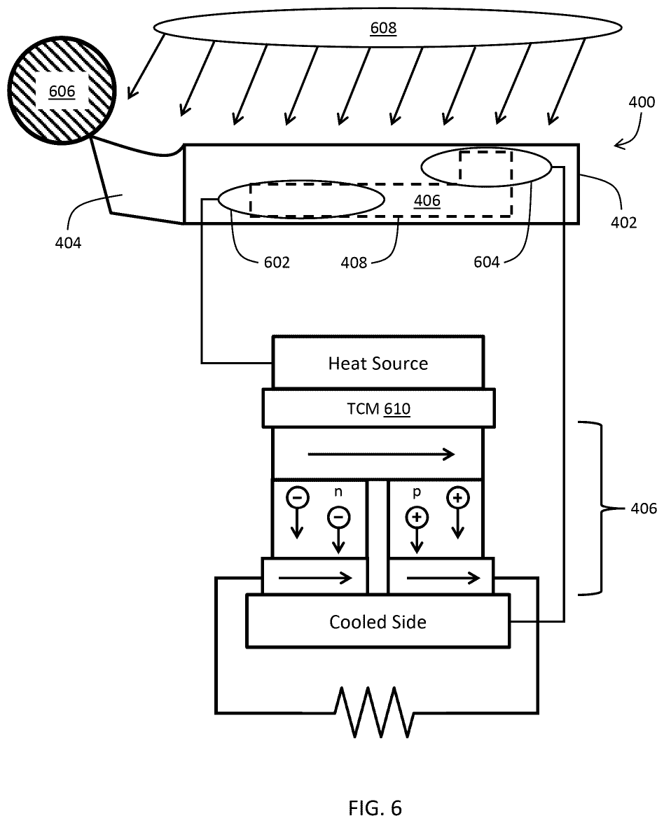

FIG. 4 depicts a side view of a cutting tool with a cavity for an integrated TEPG, in accordance with an embodiment of the present invention. In this embodiment, cutting tool 400 includes body 402 and blade portion 404, wherein thermoelectric power generation (TEPG) module 406 is disposed within cavity 408 of body 402. Blade portion 404 is of a solid hardened material that can machine (i.e., cut) a metal body resulting in heat being generated at a leading edge (i.e., tip) of blade portion 404. The heat generated at the leading edge of blade portion 404 transfers to towards TEPG module 406 through a portion of body 402. TEPG module 406 is mechanically coupled within cavity 408 utilizing one or more securing methods that include but are not limited to adhesives, clips, clamps, and fasteners. An orientation of TEPG module 406 is described in further detail with regards to FIG. 6. Dimensions of cavity 408 are such that TEPG module 406 is disposed within body 402 without compromising a structural integrity of cutting tool 400 when performing a cutting process. In one embodiment, body 402 of cutting tool 400 is molded with cavity 408 for placement of TEPG module 406. In another embodiment, body 402 is machined and material is removed to create cavity 408 for placement of TEPG module 406. TEPG module 406 is mechanically coupled to a tool holder located on cutting machine 414, where cutting machine 414 performing the cutting process on the metal body with cutting tool 400 includes power storage 416 and sensors 418. Cutting machine 414 is electrically coupled to TEPG module 406 disposed in cavity 408 of body 402 via electrical connection 420.

FIG. 5 depicts a three-dimensional view of a cutting tool with a cavity for an integrated TEPG, in accordance with an embodiment of the present invention. As previously discussed, cutting tool 400 includes TEPG module 406 disposed within cavity 408 of body 402. In this embodiment, body 402 partially encases cavity 408 with TEPG module 406 on every side except an underside of body 402 located on a lower portion of cutting tool 400. Access to cavity 408 is through the underside of body 402 which allows for insertion of TEPG module 406 into cutting tool 400 and allows for a routing of electrical connection 420 to cutting machine 414 with power storage 316 and sensor 418. Access to cavity 408 through the underside of body 402 also reduces an amount of coolant fluid that can potentially seep into cavity 408 when the coolant fluid is applied to an exterior surface of top portion of cutting tool 400.

FIG. 6 depicts a side view of a cutting tool with an integrated TEPG generating power while cutting a metal body with a coolant fluid being applied, in accordance with an embodiment of the present invention. An enhanced view of TEPG module 406 is provided to illustrate where heated area 602 of cavity 408 nearest to blade portion 404 represents a region where heat generated by cutting tool 400 is transferred to TEPG module 406 and cooled area 604 represents a region where coolant fluid applied to an exterior surface of cutting tool 400 is transferred to TEPG module. Therefore, heated area 602 represents the heat source on TEPG module 406 and cooled area 604 represents the cooled side on TEPG module 406, where a difference the temperature difference between heated area 602 and cooled area 604 generates electrical energy through the Seebeck effect. As blade portion 404 of cutting tool 400 contacts metal body 606 to remove material, heat is generated at the leading edge of blade portion 404 which is subsequently transferred through a portion of body 402 towards heated area 602 of TEPG module 406. Coolant fluid 608 is applied to the exterior surface of top portion of cutting tool 400 that includes cooled area 604 of TEPG module 406. In this embodiment, thermal conductive material (TCM) 610 is present between the heat source and TEPG module 406 to facilitate heat transfer. TCM 610 can be a thermal pad, a paste, and/or a thermal interface material (TIM) to ensure heat transfer between an interior surface of cavity 408 and TEPG module 406.

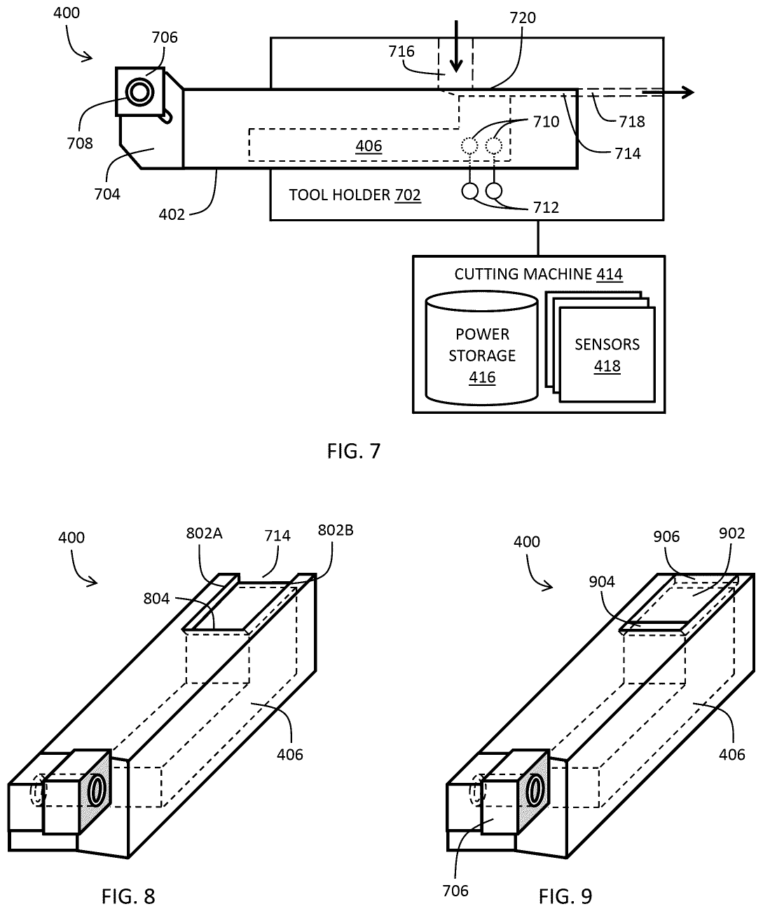

FIG. 7 depicts a side view of a cutting tool with a cavity for an integrated TEPG and a channel for directing coolant fluid, in accordance with an embodiment of the present invention. In this embodiment, cutting tool 400 is secured within tool holder 702, where an electrical connection exists between tool holder 702 and TEPG module 406 of cutting tool 400. Cutting tool 400 includes cutting blade holder 704 with cutting blade 706 for removing material from a metal body (i.e., machining), where cutting blade 706 includes aperture 708 for securing cutting blade 706 to cutting blade holder 704 utilizing a fastener such as, a screw, bolt, or rivet. A lower surface of TEPG module 406 includes two electrical contact leads 710 opposite two electrical contact pads 712 on tool holder 702. When cutting tool 400 is secured to tool holder 702, the two electrical contact leads 710 of TEPG module 406 at least partially align with two electrical contact pads 712 on tool holder 702. Electrical contact leads 710 and electrical contact pads 712 allow for TEPG module 406 to transfer generated power to tool holder 702 to power storage 416 and sensors 418 on cutting machine 414. In this embodiment, cutting tool 400 includes channel 714 on a top surface of body 402, where a top surface of TEPG module 406 is exposed to coolant fluid applied to cutting tool 400. Tool holder 702 includes inlet channel 716 located in a top portion and outlet channel 718 located in a rear portion, where coolant fluid enters inlet channel 716, passes over TEPG module 406 via channel 714 that is defined by the multiple walls that includes lower surface portion 720 of tool holder 702, and exits outlet channel 718. The heated coolant fluid that exits outlet channel 718 can be cooled and recirculated back into inlet channel 716. Channel 714 is defined by an inner surface of tool holder 702, a top surface of TEPG module 406, and multiple walls, discussed in further detail with regards to FIG. 8.

FIG. 8 depicts a three-dimensional view of a cutting tool with a cavity for an integrated TEPG and a channel for directing coolant fluid, in accordance with an embodiment of the present invention. In this embodiment, cutting tool 400 includes channel 714 previously discussed with respect to FIG. 7. Channel 714 directs coolant fluid over a cooling side of TEPG module 406, where multiple walls define a portion of channel 714. Inlet channel 716 of tool holder 702 from FIG. 7 is disposed over a portion of channel 714 and lower surface portion 720 of tool holder 702 is disposed over another remaining portion of channel 714. Lower surface portion 720 of tool holder 702 represents one of the multiple walls that define channel 714. The remaining multiple walls that define channel 714 include two side walls 802A and 802B positioned length wise with respect to cutting tool 400 and one angled wall 804 positioned width wise with respect to cutting tool 400. Angle wall 804 direct coolant fluid along channel 714 over TEPG module 406.

FIG. 9 depicts a three-dimensional view of a cutting tool with a cavity for an integrated TEPG and an enclosed channel for directing coolant fluid, in accordance with an embodiment of the present invention. In this embodiment, cutting tool 400 includes enclosed channel 902, where inlet 904 directs coolant fluid over a cooling side of TEPG module 406 through enclosed channel 902 and exits at outlet 906 at an end of cutting tool 400 located opposite cutting blade 706.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

Wat is claimed is:

1. An apparatus for a cutting tool with an integrated thermoelectric power generation (TEPG) module, the apparatus comprising:
a body and a blade portion of the cutting tool; and
the TEPG module disposed in a cavity of the body of the cutting tool.

2. The apparatus of claim 1, further comprising:
a first end of the TEPG module positioned in the body nearest to the blade portion of the cutting tool; and
a second end of the TEPG module positioned in the body opposite the first end of the TEPG module, wherein the first end presents a heat source side of the TEPG module and the second end represents a cooled side of the TEPG module.

3. The apparatus of claim 2, wherein the TEPG module is secured within the cavity of the body of the cutting tool utilizing one or more fasteners.

4. The apparatus of claim 2, wherein the TEPG module is secured within the cavity of the body of the cutting tool utilizing one or more clips.

5. The apparatus of claim 2, wherein the TEPG module is secured within the cavity of the body of the cutting tool utilizing one or more clamps.

6. The apparatus of claim 2, wherein the TEPG module is secured within the cavity of the body of the cutting tool utilizing one or more adhesives.

7. The apparatus of claim 2, wherein a thermal conductive material (TCM) is positioned between the TEPG module and an inner surface of the cavity of the body of the cutting tool.

8. The apparatus of claim 7, where the TCM is selected from the group consisting of: a thermal pad, a thermal paste, and a thermal interface material (TIM).

9. The apparatus of claim 2, further comprising:
a channel on a top surface of the body of the cutting tool, wherein the channel is positioned above the second end of the TEPG module.

10. The apparatus of claim 9, wherein the channel is partially enclosed and includes an inlet and an outlet.

11. The apparatus of claim 2, further comprising:
the cutting tool is secured in a tool holder, wherein the cutting tool is electrically coupled to the tool holder.

12. The apparatus of claim 11, further comprising:
a first electrical contact lead on the cutting tool at least partially aligns with a first electrical contact pad on the tool holder, wherein the first electrical contact lead contacts the first electrical contact pad.

13. The apparatus of claim 12, further comprising:
an inlet channel of the tool holder for directing a coolant fluid towards a channel on a top surface of the body of the cutting tool, wherein the channel is positioned above the second end of the TEPG module.

14. The apparatus of claim 13, further comprising:
an outlet channel of the tool holder for directing the coolant fluid away from the channel on the top surface of the cutting tool.

15. The apparatus of claim 14, wherein the channel on the top surface of the cutting tool is defined by a lower surface portion of the tool holder, a cooling side of the TEPG module and a plurality of walls on the top surface of the cutting tool.

16. The apparatus of claim 15, wherein the plurality of walls includes two side walls positioned length wise with respect to the cutting tool and one angled wall positioned width wise with respect to the cutting tool.

17. The apparatus of claim 2, further comprising:
a cutting blade secured to the blade portion utilizing at least one fastener.

18. The apparatus of claim 17, wherein the cutting blade includes at least one aperture for the at least one fastener for securing the cutting blade to the blade portion.

19. The apparatus of claim 18, wherein the at least one fastener is selected from the group consisting of: a screw, bolt, and rivet.

20. A computer-implemented method comprising:
identifying a cutting operation for a cutting tool with an integrated thermoelectric power generation (TEPG) module;
monitoring temperature for one or more sensors for the cutting tool with the integrated TEPG module;
determining a temperature threshold has been reached for at least one sensor from the one or more sensors, activating coolant fluid flow towards the cutting tool with the integrated TEPG module; and
generating, by the TEPG module, power based on a temperature difference from heat generated by the cutting operation at a first end of the cutting tool with the integrated TEPG module and the coolant fluid at a second end of the cutting tool with the integrated TEPG module.
